(19) United States
(12) Patent Application Publication
(10) Pub. No.: US 2005/0014035 A1
(43) Pub. Date: Jan. 20, 2005

(54) Prepreg for printed wiring board, printed wiring board using the prepreg and method for manufacturing the printed wiring board, and multilayer printed wiring board and method for manufacturing the multilayer printed wiring board

(75) Inventors: Yasushi Nakagiri, Kyotanabe-shi (JP); Shinobu Masuda, Settsu-shi (JP); Shozo Ochi, Takatsuki-shi (JP); Satoru Tomekawa, Kishiwada-shi (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO., LTD., Kadoma-shi (JP)

(21) Appl. No.: 10/890,329

(22) Filed: Jul. 12, 2004

(30) Foreign Application Priority Data
Jul. 16, 2003 (JP) 2003-275553

(51) Int. Cl. C04B 35/64; C04B 33/36; C04B 33/32; B28B 5/00; B28B 3/00; B28B 1/00; D04H 13/00; D04H 5/00; D04H 3/00; D04H 1/00; H01R 12/04; H05K 1/11; B32B 9/00; B32B 5/02; B32B 3/00

(52) U.S. Cl. 428/901; 174/110 FC; 442/59; 264/619

(57) ABSTRACT

A prepreg for a printed wiring board includes fluorocarbon fibers as a reinforcing material, and the reinforcing material is impregnated with a resin. The fluorocarbon fibers include short fibers having a branch structure. The reinforcing material includes a nonwoven fabric formed by interlacing the fluorocarbon fibers in the thickness direction. The proportion of the fluorocarbon fibers among the fibers constituting the nonwoven fabric ranges from 50 wt % to 100 wt %, and the remaining fibers are synthetic fibers or inorganic fibers. The nonwoven fabric is heat-treated at 330° C. to 390° C., then annealed at 200° C. to 270° C., and impregnated with the resin. This prepreg can used to provide a printed wiring board with low Interstitial Via Hole connection resistance and high connection stability and a method for manufacturing the printed wiring board.

### BACKGROUND OF THE INVENTION

1. Field of the Invention

The present invention relates to a prepreg for a printed wiring board used in various types of electronic equipment, a printed wiring board using the prepreg and a method for manufacturing the printed wiring board, and a multilayer printed wiring board and a method for manufacturing the multilayer printed wiring board.

2. Description of the Related Art

With recent advances in small, lightweight, and high performance electronic equipment, there has been a growing demand for a printed wiring board that is small, lightweight, and capable of providing high-density mounting and high-speed signal processing. To achieve such a printed wiring board, multilayering, smaller via holes, and the microfabrication technique for a circuit are necessary. However, it is very difficult for a conventional multilayer printed wiring board, which has a through hole structure for electrically connecting the layers, to meet the above demand. Therefore, not only a printed wiring board with a new structure, but also a printed wiring board using an organic fiber material or film as well as a general glass material has been under development.

As one typical example, the Japanese patent No. 2601128 proposes a printed wiring board having an Interstitial Via Hole (IVH) structure in all layers to make interlayer connection with a conductive paste, instead of the conventionally mainstream through hole structure. This printed wiring board includes an insulating layer made of a composite material such as aramid-epoxy resin and has the advantages of low thermal expansion, low dielectric constant, and lightweight. Thus, the printed wiring board has been used widely in many types of electronic equipment that needs to be small and lightweight.

In the conventional structure, however, the initial connection resistance increases or varies greatly with finer patterns and smaller via holes. When information processing equipment is used under high-frequency conditions, the printed wiring board should have high reliability, and particularly have excellent hygroscopic properties and high-frequency properties. One of the high-frequency properties of the printed wiring board is a transmission loss. The transmission loss includes a dielectric loss of the insulating layer and a loss of the conductor layer such as a copper foil, and the dielectric loss generally tends to be large. Therefore, a material having a low relative dielectric constant and low dielectric dissipation factor, and particularly having a low dielectric dissipation factor is suitable as a reinforcing material for suppressing the transmission loss of signals. Examples of the material with these characteristics include a fluorocarbon resin. However, the fluorocarbon resin cannot be handled easily because of its high molding temperature and low processability. Moreover, the fluorocarbon resin is chemically stable, has poor adhesion properties, and thus is not appropriate for a material of a multilayer printed wiring board.

On the other hand, a substrate made of a glass fiber core impregnated with a fluorocarbon resin rather than a fluorocarbon resin alone is commercially available. However, in addition to the above problems, this material has the following disadvantages: the glass fibers should be surface-treated for impregnation; the heat-treatment temperature at which the material is formed into a substrate is high; and the impregnating fluorocarbon resin is subjected to a special surface treatment for through hole plating. Moreover, when the printed wiring board has even finer wiring patterns, the high-frequency properties may be affected by nonuniform impregnation of the glass fibers with the fluorocarbon resin, a large difference between high dielectric properties of the glass fibers and low dielectric properties of the fluorocarbon resin, and nonuniform mixture of the glass fibers with the fluorocarbon resin.

### SUMMARY OF THE INVENTION

A prepreg for a printed wiring board of the present invention includes fluorocarbon fibers as a reinforcing material, and the reinforcing material is impregnated with a resin. The fluorocarbon fibers include short fibers having a branch structure. The reinforcing material includes a nonwoven fabric formed by interlacing the fluorocarbon fibers in the thickness direction. The proportion of the fluorocarbon fibers among the fibers constituting the nonwoven fabric ranges from 50 wt % to 100 wt %. The nonwoven fabric is heat-treated at 330° C. to 390° C. and then annealed at 200° C. to 270° C. The nonwoven fabric is impregnated with the resin.

A printed wiring board of the present invention is provided so that the above prepreg is compressed into a substrate, a patterned wiring is formed on both principal surfaces of the prepreg or the substrate, and the patterned wirings are electrically connected by a conductor in the thickness direction of the substrate.

Another printed wiring board of the present invention is formed as a multilayer printed wiring board that includes at least two wiring layers and an insulating layer for electrically insulating the wiring layers. The above prepreg is used as the insulating layer.

A method for manufacturing a printed wiring board of the present invention includes the following: forming through holes in an insulating layer made of the above prepreg; filling the through holes with a conductor; pressing and heating the prepreg into a substrate; and forming a patterned wiring on both principal surfaces of the prepreg or the substrate.

A method for manufacturing a multilayer printed wiring board of the present invention includes the following: producing a double-sided printed wiring board by the above method; layering at least two prepregs of the present invention, whose through holes are filled with a conductor, and at least two metal foils on both surfaces of the double-sided printed wiring board; heating and pressing the double-sided printed wiring board along with the at least two prepregs and metal foils; and forming the metal foils into a wiring pattern.

Another method for manufacturing a multilayer printed wiring board of the present invention includes the following: producing a plurality of double-sided printed wiring boards by the above method; arranging at least two prepregs of the present invention, whose through holes are filled with a conductor, alternately with the double-sided printed wiring boards; and heating and pressing the double-sided printed wiring boards along with the at least two prepregs so that a wiring pattern of the double-sided printed wiring board is embedded in a resin layer present in the surface of the prepreg.

### BRIEF DESCRIPTION OF THE DRAWINGS

FIGS. 1A to 1C are SEM photographs of the surface of a reinforcing material of fluorocarbon fibers in an example of the present invention.

FIG. 2 is a SEM photograph of the surface of a reinforcing material of fluorocarbon fibers in a comparative example.

FIG. 3 is a photograph of the surface of a reinforcing material using a conventional glass fiber fabric (cloth).

FIG. 4 is a graph showing the relationship between a heat treatment temperature and base material strength of a printed wiring board that includes fluorocarbon fibers as a reinforcing material in an example of the present invention.

FIG. 5 is a graph showing the relationship between a heat treatment temperature and base material elongation of the printed wiring board.

FIG. 6 is a cross-sectional view of a printed wiring board having a through hole structure.

FIG. 7 is a cross-sectional view of a printed wiring board having an IVH structure in all layers of an embodiment of the present invention.

FIGS. 8A to 8F are cross-sectional views showing the processes of manufacturing a printed wiring board having an IVH structure in all layers of Embodiment 1 of the present invention.

FIGS. 9A to 9L are cross-sectional views showing the processes of manufacturing a printed wiring board having an IVH structure in all layers of Embodiment 4 of the present invention.

FIG. 10 is a graph showing the relationship between an annealing temperature and electrical resistance in Embodiment 1 of the present invention.

### DESCRIPTION OF THE PREFERRED EMBODIMENTS

The present invention uses fluorocarbon fibers made of a fluorocarbon resin as a reinforcing material. The fluorocarbon fibers include short fibers having a branch structure. The reinforcing material includes a nonwoven fabric formed by interlacing the fluorocarbon fibers in the thickness direction. Therefore, the reinforcing material can be impregnated with a resin more uniformly than the glass fibers or conventional fluorocarbon fibers. A nonwoven fabric that is formed by interlacing ordinary fluorocarbon fibers may repel a resin due to the surface characteristics of fluorine. In contrast, the fluorocarbon fibers of the present invention include short fibers having a branch structure. Therefore, a resin is not repelled and goes deep in the fibers so that uniform resin impregnation can be ensured even in a minute region.

When a prepreg of the present invention that includes the reinforcing material impregnated with a resin is used as an insulating material, the inherently low adhesion properties of the fluorocarbon resin can be improved to make multilayering possible. Thus, the present invention can provide a multilayer printed wiring board that has high reliability in a humid environment and excellent high-frequency properties, and a method for manufacturing the multilayer printed wiring board.

Moreover, the following conditions are employed as an example of the preferred embodiment.

In the prepreg for a printed wiring board of the present invention, the short fluorocarbon fibers having a branch structure are used as a reinforcing material after heat treatment at 330° C. to 390° C., followed by annealing at 200° C. to 270° C. Then, the reinforcing material is impregnated with an organic resin.

The proportion of the fluorocarbon fibers among the fibers constituting the nonwoven fabric of this reinforcing material ranges from 50 wt % to 100 wt %, and the remaining fibers may be synthetic fibers or inorganic fibers. A variation in amount of the impregnating resin is maintained within ±5% in any portion having an area of 300 μm square. It is more preferable that the variation is maintained within ±5% in any portion having a volume of 300 μm square and 100 μm thick.

By maintaining the fluorocarbon fibers and the impregnating resin uniform, good signal transmission properties can be achieved, e.g., when high-frequency signals of several to several tens of GHz are transmitted using a wiring pattern in which the line width is 100 μm, the distance between lines is 100 μm, and the distance from, e.g., an antenna to ground is 100 μm.

In a printed wiring board and its manufacturing method, the above prepreg is processed so that a conductor is filled into the prepreg, thereby achieving the IVH structure in all layers.

The fluorocarbon fibers of the present invention may be, e.g., polytetrafluoroethylene (PTFE), tetrafluoroethylene-perfluoroalkyl vinyl ether copolymer (PFA), polychlorotrifluoroethylene (PCTFE), polyvinylidene fluoride (PVDF), polyvinyl fluoride (PVF), tetrafluoroethylene-hexafluoropropylene copolymer (FEP), or tetrafluoroethylene-ethylene copolymer (PETFE). Two or more of them can be mixed for use. Among the fluorocarbon fibers, PTFE is most preferred in view of heat resistance and high-frequency properties. Also, a chemically denatured polymer, in which only the side chain of the polymer is changed by a chemical reaction, may be used.

The fluorocarbon fibers preferably have an average fiber length of 1 mm to 50 mm. This is suitable for the formation of a nonwoven fabric. When the average fiber length is less than 1 mm, the interlacing capability between fibers is reduced, so that a high-strength nonwoven fabric may not be provided. When the average fiber length is more than 50 mm, fuzz is increased, and the thickness is not likely to be uniform. Moreover, the fluorocarbon fibers preferably have an average fineness of 1 dtex to 10 dtex. When the average fineness is less than 1 dtex, it is difficult to produce the fibers. When the average fineness is more than 10 dtex, the thickness is not likely to be uniform. The fluorocarbon fibers are preferably flat in shape. The short fluorocarbon fibers of the present invention include main fibers and branched fibers attached to the main fibers. The branched fibers are thinner and shorter than the main fibers. Such fluorocarbon fibers can be obtained by slitting a film in the longitudinal direction to make slit fibers and cutting the slit fibers into a predetermined length. This method is known, e.g., from U.S. Pat. No. 2,772,444, U.S. Pat. No. 3,953,566, U.S. Pat. No. 4,187,390, JP Patent No. 3079571, or WO96-00807.

The PTFE fibers used in the present invention may be obtained preferably by slitting and cutting a biaxially-oriented film because it has high heat resistance.

The resin impregnated into the nonwoven fabric may be either a thermoplastic resin or thermosetting resin. Examples of the thermoplastic resin include known resins such as polyethylene, polypropylene, polystyrene, polyvinyl chloride, polymethyl methacrylate, polyphenylene ether, cyanate ester, and polyurethane resin. However, the impregnating resin is not limited to these resins, and any of them may be combined appropriately. Examples of the thermosetting resin include known resins such as a phenol resin, naphthalene resin, urea resin, amino resin, alkyd resin, silicon resin, furan resin, unsaturated polyester resin, and epoxy resin. However, the impregnating resin is not limited to these resins, and any of them may be combined appropriately. In particular, when the impregnating resin is at least one resin selected from an epoxy resin, polyphenylene oxide, polyphenylene ether, and cyanate ester resin, it is suitable for integration with the fluorocarbon fibers, and the high-frequency properties can be improved. A filler such as aluminum hydroxide or silica may be added, e.g., to adjust melt viscosity or to enhance heat resistance. Moreover, an additive or solvent may be added to improve impregnation properties.

When the total amount of the impregnating resin and the reinforcing material made of a nonwoven fabric that includes the fluorocarbon fibers as the main component is 100 wt %, the impregnating resin is preferably 40 to 60 wt %, and more preferably 45 to 55 wt %. When the amount of resin is small, the adhesion between the substrate and wiring is reduced and may result in peeling. When the amount of resin is large, the resin flows out during pressing and heating and may cause a connection failure.

Other fibers (e.g., synthetic or inorganic fibers) that are added to the fluorocarbon fibers should be less than 50 wt %. The high-frequency properties are likely to be lower with an increase in additional fibers. Examples of the synthetic fibers include aramid fibers (aromatic polyamide fibers), polyphenylene sulfide (PPS) fibers, polyether ether ketone (PEEK) fibers, polyphenylene oxide (PPO) fibers, and polyimide (PI) fibers. Examples of the inorganic fibers include glass fibers and silica fibers. Among these fibers, the PEEK fibers are particularly preferred in view of high-frequency properties.

The prepreg of the present invention includes fluorocarbon fibers as the main component of a reinforcing material. The fluorocarbon fibers include short fibers having a branch structure. The reinforcing material includes a nonwoven fabric formed by interlacing the fluorocarbon fibers in the thickness direction. The nonwoven fabric is heat-treated at 330° C. to 390° C., annealed at 200° C. to 270° C., and impregnated with a resin. When this prepreg is used as an insulating material of a printed wiring board of the present invention, the inherently low adhesion properties of the fluorocarbon fibers can be improved to eliminate difficulties in multilayering. Therefore, the present invention can provide a multilayer printed wiring board that has high reliability in a humid environment and excellent high-frequency properties, and a method for manufacturing the multilayer printed wiring board.

Hereinafter, the present invention will be described in more detail by way of embodiments.

The following embodiments use “POLYFLONWEB B” manufactured by Daikin Industries, Ltd. The “POLYFLONWEB B” is a short fiber nonwoven sheet made of fluorocarbon fibers having a branch structure. The fluorocarbon fibers are produced in the following manner: a polytetrafluoroethylene (PTFE) film is fed to a revolving roller with needles, split in the longitudinal direction, and cut into a predetermined length. The resultant fibers have an average fineness of 5 dtex, an average fiber length of 15 to 20 mm, fuzz with a length of several μm, and no regular shape in cross section. The fluorocarbon fibers with a branch structure can be obtained by cutting the split fibers. The nonwoven fabric is a spun lace nonwoven fabric formed by stream (water jet) interlacing of fibers. The nonwoven fabric includes pores due to the stream interlacing and has air permeability, a porosity of not more than 75%, an apparent specific gravity of 0.5 to 0.6, a strength of not less than 7 N/cm², and a weight per unit area of 100 to 120 g/m².

Embodiment 1

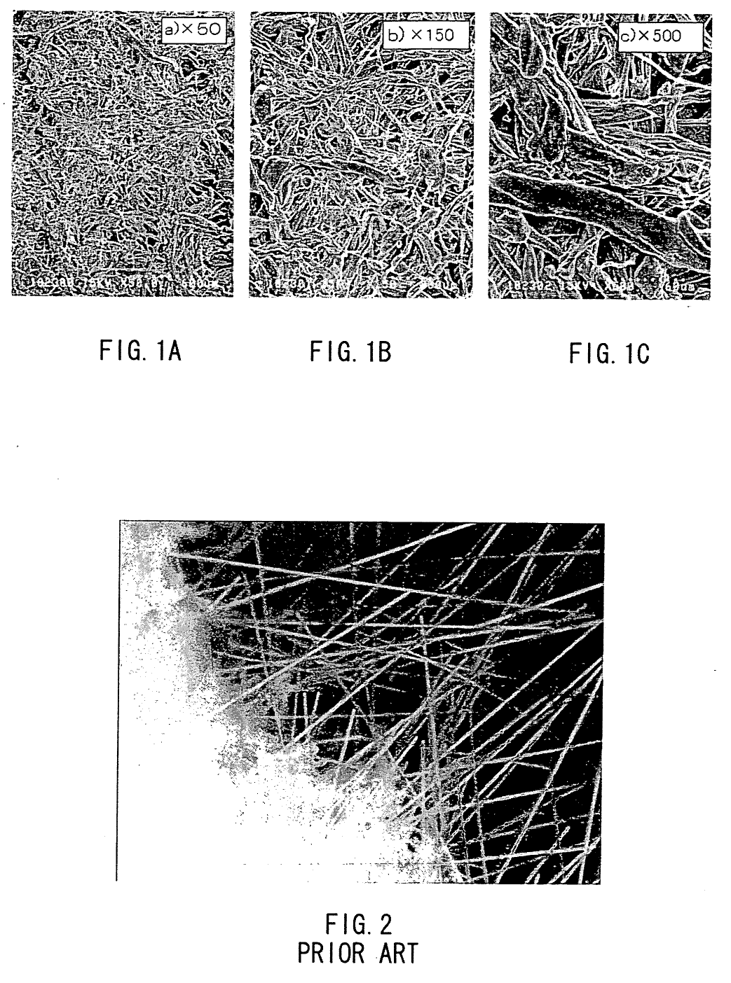

In Embodiment 1, first, the “POLYFLONWEB B” is heat-treated at temperatures from 300° C. to 400° C. in increments of 10° C. FIGS. 1A to 1C show the SEM photographs of a sample that has been heat-treated at 350° C. FIGS. 1A, 1B, and 1C show the same sample with different magnification of 50 times, 150 times, and 500 times, respectively. As can be seen from FIG. 1C, the short fibers are interlaced even in a distance of several 10 μm, and the surface is considerably uneven, so that there is no smooth surface that continuously comes into contact with a resin. Thus, the resin is not repelled and can go deep in the fibers.

FIG. 2 shows an example of a nonwoven fabric made of single straight fluorocarbon fibers that do not include short fibers having a branch structure. In FIG. 2, fibers more uniform than the fluorocarbon fibers of the present invention are interlaced. Accordingly, due to a smaller degree of unevenness of the fiber surface, a resin is repelled and cannot go deep in the fibers. A lower left portion of the photograph in FIG. 2 that appears blurred is the surface of the base material of the nonwoven fabric.

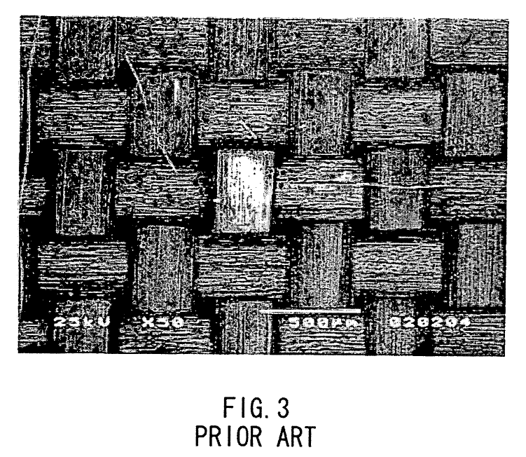

FIG. 3 shows a photograph of the surface of a glass fiber woven fabric. A prepreg that includes the glass fiber woven fabric impregnated with a resin is most widely used for a circuit board at present. For a general low-frequency circuit board, this prepreg has no problem. In the case of a fine-pitch high-frequency circuit board, however, a variation in characteristics that is inherent in the glass fiber woven fabric becomes prominent. As can be seen from FIG. 3, it is inevitable that a gap or portion having a different fiber density is created at the intersection of warp and weft yarns. Therefore, when the prepreg is observed locally, the resin impregnation density differs from portion to portion. This is not a problem in transmitting signals with a frequency of several to several tens of MHz. However, when signals with a small wavelength of several mm or a high frequency of several to several tens of GHz are transmitted, nonuniformity in the minute region, such as a gap or portion having a different fiber density that is created at the intersection of warp and weft yarns, may cause impedance mismatch and noise, and thus lead to degradation or variation in characteristics.

In contrast, the nonwoven fabric made of the fluorocarbon fibers that includes short fibers having a branch structure of the present invention can eliminate the above problems and provide a circuit board that is uniform even in the minute region and has good signal transmission properties.

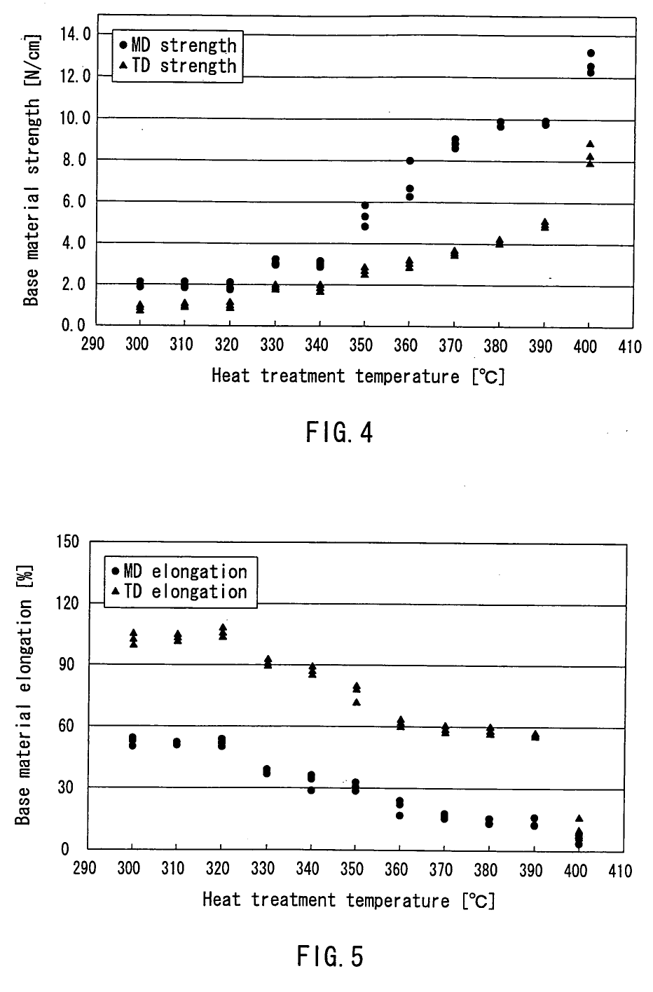

The base material strength and elongation of the “POLYFLONWEB B” that was heat-treated at temperatures from 300° C. to 400° C. in increments of 10° C. were measured. FIG. 4 shows the relationship between the heat treatment temperature and the base material strength. FIG. 5 shows the relationship between the heat treatment temperature and the base material elongation. The measurement indicates that when the temperature ranges from 330° C. to 390° C., the strength is 2 to 10 N/cm, while the elongation is 15 to 40% in a MD (machine direction) and 50 to 90% in a TD (a direction perpendicular to the MD). When the temperature is outside this range, the characteristics are changed significantly. In other words, this material can be used in the range of 330° C. to 390° C. by appropriately performing heat treatment.

Next, the heat-treated nonwoven fabric is impregnated with an epoxy resin. The relative amount of the epoxy resin is 52 wt % after drying. Consequently, when the temperature is less than 330° C., the epoxy resin is impregnated into the nonwoven fabric, but the sheet strength is a problem. Therefore, it is not possible to produce a prepreg sheet in which the resin is in a semi-rigid state (B stage) by the subsequent drying. When the temperature is more than 390° C., although the sheet strength is not a problem, the resin is repelled and not impregnated into the nonwoven fabric. The wettability of PTFE with other resins is inherently poor. However, the appropriate heat treatment of a fiber sheet such as “POLYFLONWEB B” may contribute to maintaining the state of impregnation in which the resin enters a gap between the fibers having a branch structure. The heat treatment temperature range of 330° C. to 390° C. agrees with the temperature range over which the characteristics are changed so that the base material strength increases, while the base material elongation decreases.

A circuit board is produced using the prepreg that has been heat-treated at 365° C.

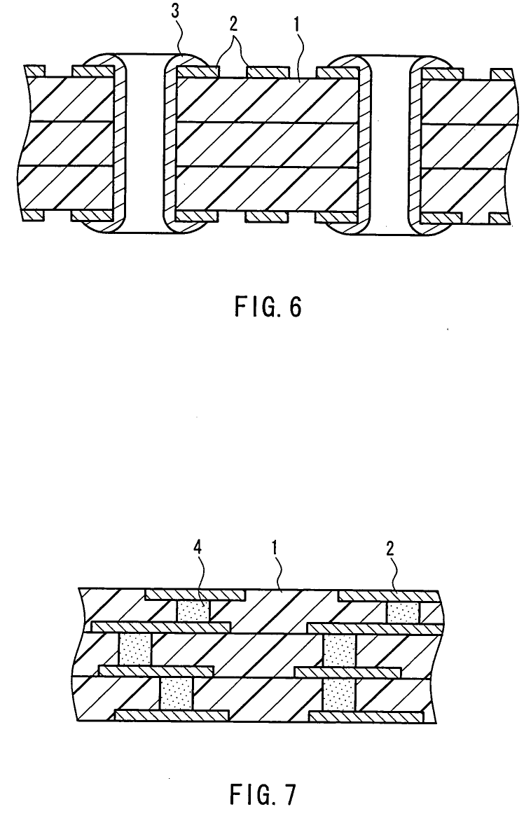

FIGS. 6 and 7 are cross-sectional views showing the structure of a printed wiring board of an embodiment of the present invention. In FIGS. 6 and 7, reference numeral 1 is an insulating layer, 2 is a wiring layer, 3 is a through hole conductor, and 4 is a via hole conductor that is filled in a hole. In each of the printed wiring boards as shown in FIGS. 6 and 7, the insulating layer 1 and the wiring layer 2 are stacked alternately, and the layers are electrically connected by the through hole conductor 3 (plated or made of conductive resin) in FIG. 6 and the via hole conductor 4 (made of conductive resin) in FIG. 7.

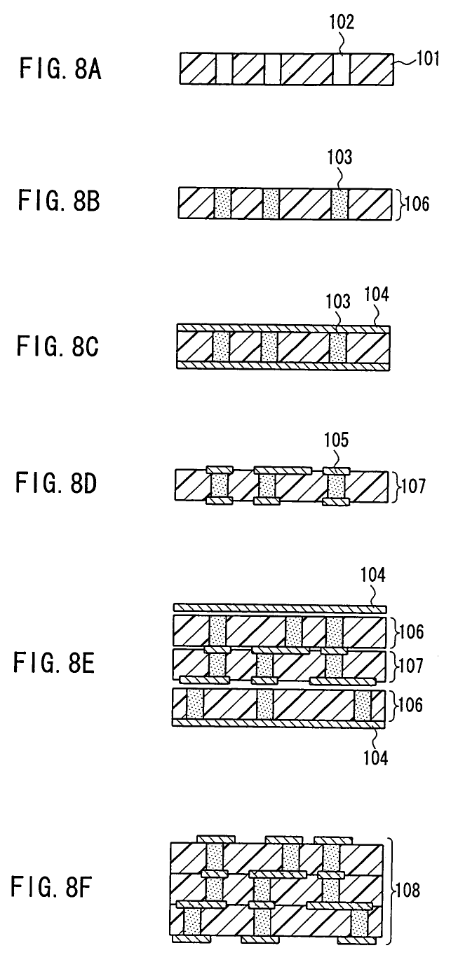

FIGS. 8A to 8F show an example of a method for manufacturing a connection intermediate and a printed wiring board. In FIGS. 8A to 8F, reference numeral 101 is an insulating layer (prepreg), 102 is a through hole, 103 is a conductor, 104 is a metal foil, 105 is a wiring pattern, 106 is a connection intermediate, 107 is a double-sided substrate, and 108 is a four-layer substrate.

The prepreg 101 uses the “POLYFLONVVEB B” that has been heat-treated at 365° C. as a reinforcing material, and the reinforcing material is impregnated with a thermosetting epoxy resin. First, through holes 102 are formed in the predetermined positions of the prepreg 101 by laser beam machining (FIG. 8A). The through holes 102 are filled with a conductive paste 103 including copper powder and an epoxy resin, so that a connection intermediate 106 is produced (FIG. 8B). Next, a copper foil 104 is formed on both surfaces of the connection intermediate 106, and then is heated and pressed at 200° C. and 4.9 MPa for 1 hour, thereby forming a thermosetting resin body with the copper foil on both surfaces (FIG. 8C). Subsequently, inner layer wiring patterns 105 are formed by etching, and thus a double-sided substrate 107 is produced (FIG. 8D). The double-sided substrate 107 is sandwiched between connection intermediates 106 that are prepared beforehand, on both surfaces of which a copper foil 104 is formed (FIG. 8E). After the resultant laminate is heated and pressed under the above conditions, outer layer circuit patterns are formed by etching, thus providing a four-layer printed wiring board 108 (FIG. 8F).

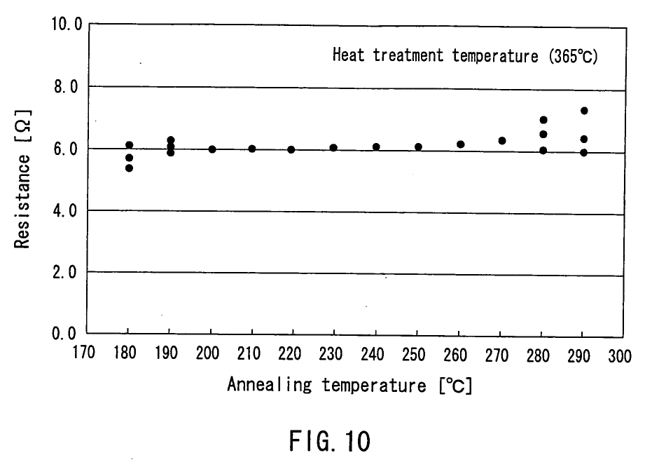

The initial resistance of the printed wiring board was measured. The measurement indicates that the resistance varies significantly. The reason for this is considered to be as follows. Although the first heat treatment provides appropriate conditions for the resin impregnation, the degree of expansion may differ between local portions due to high temperatures, thus causing heat distortion. The heat distortion may not be relaxed because the prepreg is placed in a heat and pressure molding die while it is formed into a substrate. Therefore, to remove the heat distortion, annealing is performed after the first heat treatment and before the resin impregnation at a lower temperature than the heat treatment temperature. Samples were annealed at temperatures from 180° C. to 290° C. in increments of 10° C., and then impregnated with a resin. Thereafter, a variation in electrical resistance was observed. FIG. 10 shows the results.

In FIG. 10, the resistance value is a total resistance including a wiring resistance when series vias for joining the upper and lower surfaces of a four-layer printed wiring board, which is manufactured in the above manner, are connected in 300 chains. In this case, the samples were heat-treated at 365° C., and three samples were prepared for each annealing temperature so as to observe a variation in resistance. As can be seen from FIG. 10, the variation is not reduced at annealing temperatures of 180° C., 190° C., 280° C., and 290° C. However, the variation is reduced significantly and kept substantially constant at annealing temperatures from 200° C. to 270° C., although the resistance increases gradually with temperature.

Considering the results as described above, samples are heat-treated at 365° C. and then annealed at 250° C. in Embodiment 1.

Embodiment 2

A four-layer printed wiring board is manufactured by the same method as that in Embodiment 1, except for the use of a prepreg obtained in the following manner: a nonwoven fabric (“POLYFOLNWEB B”) made of fluorocarbon fibers is heat-treated at 365° C., annealed at 250° C., and then impregnated with polyphenylene oxide (the relative amount of the polyphenylene oxide is 52 wt % after drying).

Embodiment 3

A four-layer printed wiring board is manufactured by the same method as that in Example 1, except for the use of a prepreg obtained in the following manner: a nonwoven fabric formed by mixing fluorocarbon fibers and glass fibers (fluorocarbon fibers: 85 wt %, glass fibers: 15 wt %) is heat-treated at 365° C., annealed at 250° C., and then impregnated with a thermosetting epoxy resin (the relative amount of the thermosetting epoxy resin is 52 wt % after drying).

Embodiment 4

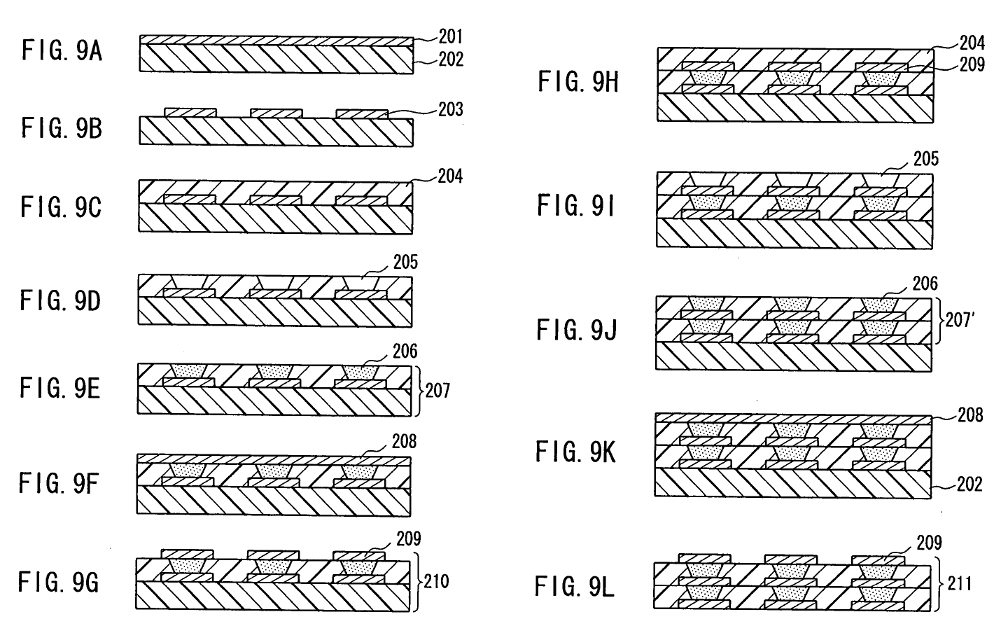

FIGS. 9A to 9L show an example of a method for manufacturing a connection intermediate and a printed wiring board in Embodiment 4 of the present invention. In FIGS. 9A to 9L, reference numeral 201 is a metal foil, 202 is a supporting base, 203 is a wiring pattern, 204 is an insulating layer (prepreg), 205 is a through hole, 206 is a conductor, 207 is a connection intermediate, 208 is a metal foil, 209 is a wiring pattern, 210 is a double-sided substrate, and 211 is a three-layer substrate.

First, a copper foil 201 is formed on the supporting base 202, and a convex wiring pattern 203 is formed at the predetermined position of the supporting base 202 by etching (FIGS. 9A to 9B). The prepreg 204 includes a nonwoven fabric (“POLYFOLNWEB B”) made of fluorocarbon fibers, and the nonwoven fabric is impregnated with a thermosetting epoxy resin (the relative amount of the thermosetting epoxy resin is 52 wt % after drying). Then, through holes 205 are formed in the predetermined positions of the prepreg 204 by a blind via process using a laser or the like (FIGS. 9C to 9D). The through holes 205 are filled with a conductive paste 206 including copper powder and an epoxy resin, so that a connection intermediate 207 is produced (FIG. 9E). Next, a copper foil 208 is formed on the surface of the connection intermediate 207, and then is heated and pressed at 200° C. and 4.9 MPa for 2 hours. Subsequently, a convex wiring pattern 209 is formed by etching, and thus a double-sided substrate 210 is produced (FIGS. 9F to 9G). Moreover, through holes 205 are formed in the predetermined positions of the prepreg 204 by the blind via process using a laser or the like (FIGS. 9H to 9I). The through holes 205 are filled with the conductive paste 206 including copper powder and an epoxy resin, so that a connection intermediate 207′ is produced (FIG. 9J). Next, a copper foil 208 is formed on the surface of the connection intermediate 207′, and then is heated and pressed under the above conditions. Subsequently, an outer layer circuit pattern is formed by etching, and the supporting base 202 is removed, thus providing a three-layer printed wiring board 211 (FIGS. 9K to 9L).

Embodiment 5

A printed wiring board is manufactured by the same method as that in Embodiment 1, except for the use of a prepreg obtained in the following manner: 90 wt % of fluorocarbon fibers used in the “POLYFLONWEB B” and 10 wt % of PEEK short fibers (having a diameter of about 8 μm and a length of about 20 mm) are mixed into a fiber sheet; a highly pressurized water stream of 5 Mpa is sprayed onto the fiber sheet by a stream nozzle so that fibers constituting the fiber sheet are interlaced to form a nonwoven fabric; and the nonwoven fabric is heat-treated at 365° C., annealed at 250° C., and then impregnated with a thermosetting epoxy resin (the relative amount of the thermosetting epoxy resin is 52 wt % after drying).

Tables 1 and 2 show the evaluation of the printed wring boards produced in Embodiments 1 to 5.

### COMPARATIVE EXAMPLE 1

A four-layer printed wiring board was manufactured by the same method as that in Embodiment 1, except for the use of a prepreg that included a glass fiber reinforcing material impregnated with a thermosetting epoxy resin.

### COMPARATIVE EXAMPLE 2

This example was intended to produce a prepreg impregnated with a thermosetting epoxy resin by using the conventional fluorocarbon fibers (as shown in FIG. 2) as a reinforcing material. However, the reinforcing material was not impregnated sufficiently with the resin even by the same heat-treatment as that in Embodiment 1.

Table 1 shows the results of the connection reliability evaluation (PCT test, high temperature and humidity environmental test, and popcorn test) of the printed wiring boards in Embodiment 1 to 5 and Comparative example 1.

TABLE 1

| Samples | Test types | Evaluation* |
|---|---|---|
| Embodiment 1 | PCT test | A |
| | 85° C./85% RH/168 Hr | A |
| | Popcorn test | A |
| Embodiment 2 | PCT test | A |
| | 85° C./85% RH/168 Hr | A |
| | Popcorn test | B |
| Embodiment 3 | PCT test | A |
| | 85° C./85% RH/168 Hr | A |
| | Popcorn test | A |
| Embodiment 4 | PCT test | B |
| | 85° C./85% RH/168 Hr | A |
| | Popcorn test | A |
| Embodiment 5 | PCT test | B |
| | 85° C./85% RH/168 Hr | A |
| | Popcorn test | A |
| Comparative example 1 | PCT test | B |
| | 85° C./85% RH/168 Hr | B |
| | Popcorn test | C |

Note
*A rate of change in connection resistance is A: less than 3%, B: not less than 3 to less than 5%, and C: not less than 5 to less than 10%

The PCT test was conducted to measure a connection resistance of the samples after treating them under the conditions of 121° C. and 0.2 MPa for 300 hours. The popcorn test was conducted to measure a connection resistance of the samples after treating them under the conditions of 85° C. and 85% RH for 168 hours, followed by reflow of 260/30 sec. The high temperature and humidity environmental test was conducted to measure a connection resistance of the samples after treating them under the conditions of 85° C. and 85% RH for 168 hours. Consequently, the rate of change in connection resistance of the samples was measured in each of the tests. The connection resistance was measured by a four-terminal method with 3456A (manufactured by Hewlett-Packard Company)

As can be seen from Table 1, when the prepreg including a nonwoven fabric made of fluorocarbon fibers was used as an insulating layer, a printed wiring board was provided with excellent hygroscopic properties. Moreover, the use of the nonwoven fabric improved the connection reliability.

Two or more portions that did not include wiring and vias were cut arbitrarily from each of the prepregs and the resultant circuit boards used in Embodiments and Comparative example. Then, each of the portions was adjusted to have a thickness of 100 μm, and the thickness was measured. Subsequently, each sample thus adjusted was placed on a dicer, the dicer was set to 300 μm pitch, and thus the sample was cut into 300 μm square pieces. In this case, 150 pieces per sample were prepared. After measuring the weight of each of the pieces, the resin component was dissolved in an organic solvent and removed. Then, the weight of each of the pieces was measured again. The measurement showed that a variation in amount of the impregnating resin was within ±5% in both the prepregs and the circuit boards after curing of the resin in Embodiments 1 to 5. However, when the glass fiber reinforcing material of the comparative example was impregnated with a thermosetting epoxy resin, a variation in amount of the impregnating resin did not fall in the range of ±5%. Consequently, the prepreg and circuit board of the present invention ensured uniform resin impregnation even in a minute region.

Moreover, a dielectric constant and dielectric loss were measured with a molecular orientation meter to evaluate the high-frequency properties of the samples. Table 2 shows the results.

TABLE 2

| Samples | Test types | Measured value |
|---|---|---|
| Embodiment 1 | Dielectric constant ε | 2.7 |
| | Dielectric loss tanδ | 0.013 |
| Embodiment 2 | Dielectric constant ε | 2.5 |
| | Dielectric loss tanδ | 0.003 |
| Embodiment 3 | Dielectric constant ε | 2.7 |
| | Dielectric loss tanδ | 0.017 |
| Embodiment 4 | Dielectric constant ε | 2.7 |
| | Dielectric loss tanδ | 0.014 |
| Embodiment 5 | Dielectric constant ε | 2.6 |
| | Dielectric loss tanδ | 0.008 |
| Comparative example 1 | Dielectric constant ε | 4.8 |
| | Dielectric loss tanδ | 0.015 |

As can be seen from Table 2, when the prepreg including a nonwoven fabric made of fluorocarbon fibers was used as an insulating layer, both the dielectric constant and the dielectric loss were reduced.

In the embodiments of the present invention, a copper foil is used for a metal foil circuit pattern. However, the present invention is not limited thereto, and known metal foils such as a stainless foil, an aluminum foil, and a nickel foil can be used as well.

Moreover, the prepreg impregnated with a thermosetting epoxy resin and polyphenylene oxide resin (PPO) is used as an insulating layer. However, the present invention is not limited thereto, and known thermosetting resins such as a phenol resin, naphthalene resin, urea resin, amino resin, alkyd resin, silicon resin, furan resin, unsaturated polyester resin, and epoxy resin can be used as well. The prepreg that forms the insulating layer 1 can be used by combining any of these thermosetting resins and provide the same effect as that of each of the embodiments.

Further, a conductive paste including copper powder and an epoxy resin is used as a conductor. However, the present invention is not limited thereto, and known conductors such as plating, metal bump, or metal, high-molecular weight compounds, and a conductive adhesive produced by combining these materials can be used as well. In particular, the conductive adhesive includes conductive powder and a binder resin. The conductive powder may be, e.g., metal powder such as copper, silver, nickel, and aluminum or powder with a coating of the metal. The conductive powder may be in any forms of powder, flake, and sphere or have no regular form. Examples of the binder resin include known high-molecular weight compounds such as a phenol resin, naphthalene resin, urea resin, amino resin, alkyd resin, silicon resin, furan resin, unsaturated polyester resin, epoxy resin, and polyurethane resin. These compounds may be combined appropriately. Moreover, an additive or solvent may be added to adjust viscosity or to improve oxidation stability of the conductor.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A prepreg for a printed wiring board comprising:
fluorocarbon fibers as a reinforcing material, the reinforcing material being impregnated with a resin,
wherein the fluorocarbon fibers include short fibers having a branch structure,
the reinforcing material includes a nonwoven fabric formed by interlacing the fluorocarbon fibers in a thickness direction,
a proportion of the fluorocarbon fibers among fibers constituting the nonwoven fabric ranges from 50 wt % to 100 wt %,
the nonwoven fabric is heat-treated at 330° C. to 390° C. and then annealed at 200° C. to 270° C., and
the nonwoven fabric is impregnated with a resin.

2. The prepreg according to claim 1, wherein the fluorocarbon fibers are in the range of 40 wt % to 60 wt %, and the impregnating resin is in the range of 40 wt % to 60 wt %.

3. The prepreg according to claim 1, wherein a variation in amount of the impregnating resin is maintained within ±5 wt % in any portion having an area of 300 μm square.

4. The prepreg according to claim 1, wherein the fluorocarbon fibers have an average fiber length of 1 mm to 50 mm.

5. The prepreg according to claim 1, wherein the fluorocarbon fibers have an average fineness of 1 dtex to 10 dtex.

6. The prepreg according to claim 1, wherein the fibers that constitute the nonwoven fabric are interlaced using a pressurized stream of water so that pores are formed in the nonwoven fabric.

7. The prepreg according to claim 1, wherein the resin impregnated into the nonwoven fabric is a thermosetting resin or thermoplastic resin.

8. The prepreg according to claim 1, wherein the resin impregnated into the nonwoven fabric is at least one resin selected from the group consisting of an epoxy resin, polyphenylene oxide, polyphenylene ether, and cyanate ester resin.

9. The prepreg according to claim 1, wherein the fluorocarbon fibers are flat in shape.

10. The prepreg according to claim 1, wherein the fluorocarbon fibers are slit fibers obtained by slitting a film in a longitudinal direction.

11. The prepreg according to claim 1, wherein the remaining fibers among the fibers constituting the nonwoven fabric are synthetic fibers or inorganic fibers.

12. A printed wiring board comprising:
a prepreg comprising fluorocarbon fibers as a reinforcing material, the reinforcing material being impregnated with a resin,
wherein the fluorocarbon fibers include short fibers having a branch structure,
the reinforcing material includes a nonwoven fabric formed by interlacing the fluorocarbon fibers in a thickness direction,
a proportion of the fluorocarbon fibers among fibers constituting the nonwoven fabric ranges from 50 wt % to 100 wt %,
the nonwoven fabric is heat-treated at 330° C. to 390° C. and then annealed at 200° C. to 270° C., and
the nonwoven fabric is impregnated with a resin, and
wherein the prepreg is compressed into a substrate,
a patterned wiring is formed on both principal surfaces of the prepreg or the substrate, and
the patterned wirings are connected electrically by a conductor in a thickness direction of the substrate.

13. The printed wiring board according to claim 12, wherein a variation in amount of the impregnating resin is maintained within ±5% in any portion of the compressed prepreg that has an area of 300 μm square.

14. The printed wiring board according to claim 12, wherein two or more printed wiring boards are layered so as to form a multilayer substrate.

15. A method for manufacturing a printed wiring board with a prepreg,
the prepreg comprising fluorocarbon fibers as a reinforcing material, the reinforcing material being impregnated with a resin,
wherein the fluorocarbon fibers include short fibers having a branch structure,
the reinforcing material includes a nonwoven fabric formed by interlacing the fluorocarbon fibers in a thickness direction,
a proportion of the fluorocarbon fibers among fibers constituting the nonwoven fabric ranges from 50 wt % to 100 wt %,
the nonwoven fabric is heat-treated at 330° C. to 390° C. and then annealed at 200° C. to 270° C., and
the nonwoven fabric is impregnated with a resin,
the method comprising:
forming through holes in the thickness direction of the prepreg;
filling the through holes with a conductor;
pressing and heating the prepreg into a substrate; and
forming a patterned wiring on both principal surfaces of the prepreg or the substrate.

16. The method according to claim 15, wherein a metal foil is formed on both surfaces of the prepreg, the prepreg provided with the metal foils is then heated and pressed, and the metal foils are formed into patterned wirings.

17. The method according to claim 15, wherein a supporting base having a convex wiring pattern is formed on at least one surface of the prepreg when the prepreg is pressed and heated.

18. A method for manufacturing a multilayer printed wiring board comprising:
producing a double-sided printed wiring board by the method according to claim 15;
layering at least two prepregs as claimed in claim 15, whose through holes are filled with a conductor, and at least two metal foils on both surfaces of the double-sided printed wiring board;
heating and pressing the double-sided printed wiring board along with the at least two prepregs and metal foils; and
forming the metal foils into a wiring pattern.

19. The method according to claim 18, wherein the formation of the wiring pattern further comprises:
forming a supporting base having a convex wiring pattern on at least one surface of the prepreg;
heating and pressing the prepreg provided with the supporting base;
embedding the convex wiring pattern in the prepreg; and
removing the supporting base while leaving the wiring pattern.

20. A method for manufacturing a multilayer printed wiring board comprising:
producing a plurality of double-sided printed wiring boards by the method according to claim 15;
arranging at least two prepregs as claimed in claim 15, whose through holes are filled with a conductor, alternately with the double-sided printed wiring boards; and
heating and pressing the double-sided printed wiring boards along with the at least two prepregs so that a wiring pattern of the double-sided printed wiring board is embedded in a resin layer present in a surface of the prepreg.

21. The method according to claim 20, wherein the formation of the wiring pattern further comprises:
forming a supporting base having a convex wiring pattern on at least one surface of the prepreg;
heating and pressing the prepreg provided with the supporting base;
embedding the convex wiring pattern in the prepreg; and
removing the supporting base while leaving the wiring pattern.
